(19) United States
(12) Patent Application Publication
(10) Pub. No.: US 2006/0199295 A1
(43) Pub. Date: Sep. 7, 2006

(54) Image sensor and methods of forming the same

(75) Inventors: Jong-Wook Hong, Seoul (KR); June-Taeg Lee, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/369,474

(22) Filed: Mar. 7, 2006

(30) Foreign Application Priority Data
Mar. 7, 2005 (KR) 10-2005-18763

(51) Int. Cl. H01L 21/00

(52) U.S. Cl. 438/48

(57) ABSTRACT

A method of forming an image sensor is provided. The method includes forming a protection insulating layer, a lower mold insulating layer and an upper mold insulating layer over a semiconductor substrate in which a plurality of photodiodes are spaced apart from one another. The method further includes forming a dummy pattern contact with the lower mold insulating layer in the upper mold insulating layer, forming a preliminary cavity exposing the lower mold insulating layer contact with the dummy pattern by selectively removing the dummy pattern, and forming a cavity exposing the protection insulating layer over the photodiode by anisotropically etching the exposed lower mold insulating layer.

This application claims priority from Korean Patent Application No. 10-2005-18763 filed on Mar. 7, 2005 in the Korean Intellectual Property Office, the disclosure of which is hereby incorporated by reference herein in its entirety.

### BACKGROUND OF THE INVENTION

1. Field of the Invention

The present invention relates to a semiconductor device and a method of forming the same, and more particularly, to an image sensor and a method of forming the same.

2. Description of the Related Art

Typically, an image sensor is a device that employs a photodiode as a photodetector for converting incident light into an electrical signal. For example, external light incident upon a depletion region of the photodiode of an image sensor generates electron-hole pairs (EHPs), and signal charges are accumulated in the photodiode. The accumulated signal charges are then outputted by an operational signal to convert the external light into an electrical signal.

In recent years, fabrication technology for complementary metal oxide semiconductor (CMOS) image sensors has become more highly developed, due to certain beneficial features of CMOS image sensors such as their low power consumption and their ability to be adapted for embodying a highly integrated device. A pixel of the CMOS image sensor, in general, includes a photodiode for converting incident light into the electrical signal, and at least one Metal Oxide Semiconductor (MOS) transistor for processing signal charges generated from the photodiode.

In the CMOS image sensor, multi-layered interconnections may be formed for constituting the pixel and/or a peripheral circuit. For instance, an aluminum interconnection obtained by patterning an aluminum layer is typically used for forming the above interconnections. However, as CMOS image sensors have become more and more micronized, there has also been a corresponding need for a method of forming interconnections which are significantly more micronized and which have relatively lower resistivity than the current metal interconnections. To meet the above needs, a method of forming interconnections of CMOS image sensors using a damascene process has been developed. When forming interconnections by means of the damascene process, it is possible to effectively pattern a micronized interconnection and also to form an interconnection using copper which has a low resistivity.

For example, with a CMOS image sensor, a plurality of types of insulating layers may be stacked over the photodiode of the pixel in the image sensor. Particularly, insulating layers for insulating copper interconnections, etch stop layers for the damascene process, and/or barrier insulating layers for preventing diffusion of copper atoms may be formed over the photodiode in a CMOS image sensor. However, some of the insulating layers formed over the photodiode may have low light transmissivity with respect to incident light. For instance, it is well known that a silicon nitride layer or the like generally utilized as a diffusion barrier layer and/or the etch stop layer in forming a CMOS image sensor, has a low light transmissivity with respect to incident light. Consequently, if an insulating layer having a low absorption efficiency for incident light is arranged over the photodiode, the intensity of the incident light is lowered, thereby resulting in the photosensitivity of the image sensor deteriorating in the long run as well. Therefore, it is preferable to remove the insulating layer of low light transmissivity formed over the photodiode in a subsequent process. A conventional method of removing the insulating layer stacked over the photodiode will be described more fully with reference to FIGS. 1 and 2.

FIGS. 1 and 2 are cross-sectional views illustrating a conventional method of forming an image sensor.

Referring to FIG. 1, n-type impurity ions are selectively injected into a semiconductor substrate 1 doped with p-type impurities to form an n-type impurity diffusion layer 2. The n-type impurity diffusion region 2 constructs a p-n junction with the semiconductor substrate 1 so as to form a photodiode.

Thereafter, an oxide layer 3 is formed on the semiconductor substrate 1, and a plurality of mold layers 6 are formed on the oxide layer 3, wherein the mold layer 6 is formed by stacking a silicon nitride layer 4 and a silicon oxide layer 5 sequentially. A copper interconnection 7 is then formed in the plurality of the stacked mold layers 6. The copper interconnection 7 plays a role in operating a MOS transistor in the pixel of the image sensor. The copper interconnection is also formed in a peripheral region in which peripheral circuits are formed, but not over the n-type impurity diffusion layer 2.

The silicon nitride layer 4 may perform a function as an etch stop layer when a groove and/or a contact hole for forming the copper interconnection 7 is provided. Additionally, the silicon nitride layer 4 may perform a function for preventing the diffusion of the copper atoms. A mask layer 8 is formed on an uppermost layer of the mold layers 6, and is patterned to form an opening 9, thereby exposing a predetermined portion of the uppermost mold layer 6.

Referring to FIG. 2, the plurality of the mold layers 6 are anisotropically etched in sequence using the mask layer 7 having the opening 9 as an etch mask to form a cavity 10, thereby exposing the oxide layer 3 disposed on the n-type impurity diffusion layer 2. The oxide layer 3 protects the n-type impurity diffusion layer 2.

According to the conventional method of forming the image sensor, the cavity 10 is formed by anisotropically etching the plurality of the mold layers 6 in sequence. However, due to the significant thickness of the plurality of the mold layers 6, the cavity 10 is formed such that sidewalls thereof are inclined after etching. Consequently, edges of the n-type impurity diffusion layer 2 are shielded by the plurality of the mold layers 6 so that the open region of the photodiode is reduced. When the open region of the photodiode is reduced, the quantity of the incident light decreases as well, which in turn may also cause the photosensitivity of the image sensor to be deteriorate. In addition, when the open region of the photodiode is reduced, the tilt angle of the inclined sidewall of the cavity 10 may be irregular which in turn may cause, the alignment margin between the n-type impurity diffusion layer 2 and the opening 9 to decrease, thereby possibly also decreasing the productivity of the CMOS image sensor.

Accordingly, there is a need for an image sensor and a method of forming the same, having improved photosensitivity in comparison to conventional image sensors. In addition, there is a need for an image sensor and method of forming the same, wherein crosstalk between adjacent pixels is minimized in comparison to conventional image sensors.

### SUMMARY OF THE INVENTION

In an exemplary embodiment of the invention a method of forming an image sensor is provided. The method includes forming a protection insulating layer, a lower mold insulating layer and an upper mold insulating layer over a semiconductor substrate in which a plurality of photodiodes are spaced apart from one another. The method further includes forming a dummy pattern contact with the lower mold insulating layer in the upper mold insulating layer, forming a preliminary cavity exposing the lower mold insulating layer contact with the dummy pattern by selectively removing the dummy pattern, and forming a cavity exposing the protection insulating layer over the photodiode by anisotropically etching the exposed lower mold insulating layer.

In other exemplary embodiments, the forming of the upper mold insulating layer and the dummy pattern may include following steps. An interconnection mold layer may be formed over the lower mold insulating layer. A dummy opening may be formed in the interconnection mold layer. A filling pattern is formed to fill the dummy opening. At this time, the upper mold insulating layer may include the interconnection mold layer and the dummy pattern includes the filling pattern. The forming of the interconnection mold layer, the forming of the dummy opening and the forming of the filling pattern may be performed repeatedly a plurality of times. At this point, the upper mold insulating layer may include a plurality of stacked interconnection mold layers and the dummy pattern may include a plurality of stacked filling patterns. It is preferable that the filling pattern disposed at a lowermost portion of the stacked filling patterns be in contact with the lower mold insulating layer and the filling pattern disposed at an uppermost portion be exposed. The interconnection mold layer may include a barrier insulating layer and an interlayer dielectric layer stacked in sequence. The barrier insulating may have an etching selectivity with respect to the interlayer dielectric layer. The semiconductor substrate may have a pixel region where the photodiodes are formed and the pixel region where a peripheral circuit is formed. At this point, the method may further include forming a peripheral metal interconnection with at least one layer in the upper mold insulating layer of a peripheral region. The dummy pattern and the peripheral metal interconnection with at least one layer may be formed of the same material. It is preferable that a portion of the upper mold insulating layer disposed between the photodiodes be etched by the anisotropic etching.

In some exemplary embodiments, the present invention may further include forming a mask layer on the upper mold insulating layer; and forming an opening exposing the dummy pattern by patterning the mask layer. At this point, a width of the patterned mask layer formed on the upper mold insulating layer disposed between the photodiodes may be less than a width of the upper mold insulating layer disposed between the photodiodes. The lower mold insulating layer and edges of the upper mold insulating layer disposed between the photodiodes may be etched by performing the anisotropic etching using the patterned mask layer as an etch mask. The method may further include forming a crosstalk prevention barrier in the upper mold insulating layer. The crosstalk barrier may be disposed under the patterned mask layer formed between the photodiodes. The crosstalk prevention barrier may be upwardly spaced apart from a top surface of the lower mold layer. The crosstalk prevention barrier and the dummy pattern may be formed of the same material. The method may further include forming a pixel metal interconnection with at least one layer in the lower mold insulating layer. It is preferable that the pixel metal interconnection be formed in the lower mold insulating layer disposed between the photodiodes, and a lower portion of the upper mold insulating layer disposed over the pixel metal interconnection remain in anisotropically etching. It is preferable that a top surface of the pixel metal interconnection be in contact with the remained upper mold insulating layer and a bottom surface of the upper mold insulating layer be formed of an insulating material for preventing diffusion of metal atoms in the pixel metal interconnection.

In other exemplary embodiments, an entire surface of the upper mold insulating layer disposed between the photodiodes may be etched by the anisotropic etch. In this case, the method may further include forming a pixel metal interconnection with at least one layer in the lower mold insulating layer. The pixel metal interconnection may be formed in the lower mold insulating layer disposed between the photodiodes, and the lower portion of the upper mold insulating layer disposed over the pixel metal interconnection may remain in the anisotropic etch.

It is preferable that a top surface of the pixel metal interconnection be in contact with the remained upper mold insulating layer, and a bottom surface of the upper mold insulating layer be formed of an insulating material for preventing diffusion of metal atoms in the pixel metal interconnection.

In further exemplary embodiments, it is preferable that the dummy pattern be removed by a wet etch. The method may further include forming a transparent insulating layer filling the cavity over the semiconductor substrate, after the forming the cavity.

In another exemplary embodiment of the present invention, an image sensor is provided. The image sensor includes a semiconductor substrate in which a plurality of photodiodes are spaced apart from one another, a protection insulating layer, a lower mold insulating layer and an upper mold insulating layer stacked over the semiconductor substrate. The image sensor further includes a transparent insulating layer which fills a cavity, wherein the cavity is formed such that it penetrates through the upper and the lower mold insulating layers to expose the protection insulating layer disposed over the photodiode. Further, the image sensor also includes a crosstalk prevention barrier formed in the upper mold insulating layer disposed between the photodiodes.

In some exemplary embodiments, it is preferable that at least a portion of the cavity formed in the upper mold insulating layer have a width greater than a width of the cavity formed in the lower mold insulating layer. The semiconductor substrate may have a pixel region where the photodiodes are formed and the peripheral region where a peripheral circuit is formed. At this time, the image sensor may further include a peripheral metal interconnection with at least one layer in the upper mold insulating layer of a peripheral region. The crosstalk prevention barrier may include a material same with the peripheral metal interconnection. The image sensor may further include a pixel metal interconnection with at least one layer in the lower mold insulating layer disposed between the photodiodes. It is preferable that the crosstalk prevention barrier be arranged upwardly spaced apart from the lower mold insulating layer, and a lower portion of the upper mold insulating layer disposed under the crosstalk prevention barrier cover the lower mold insulating layer. It is preferable that the pixel metal interconnection be in contact with the upper mold insulating layer and a bottom surface of the upper mold insulating layer be formed of an insulating material for protecting diffusion of metal atoms in the pixel metal interconnection.

### BRIEF DESCRIPTION OF THE DRAWINGS

The accompanying drawings, which are included to provide a further understanding of the invention and are incorporated in and constitute a part of this application, illustrate exemplary embodiment(s) of the invention and together with the description serve to explain the principle of the invention. In the drawings:

FIGS. 1 and 2 are cross-sectional views illustrating a conventional method of forming an image sensor;

FIGS. 3 to 9 are cross-sectional views illustrating a method of forming an image sensor according to an exemplary embodiment of the present invention;

FIGS. 10 to 13 are cross-sectional views illustrating according to an exemplary embodiment of the present invention;

FIGS. 14 to 17 are cross-sectional views illustrating a method of forming an image sensor according to an exemplary embodiment of the present invention; and

FIG. 18 is a cross-sectional view of an image sensor according to an exemplary embodiment the present invention.

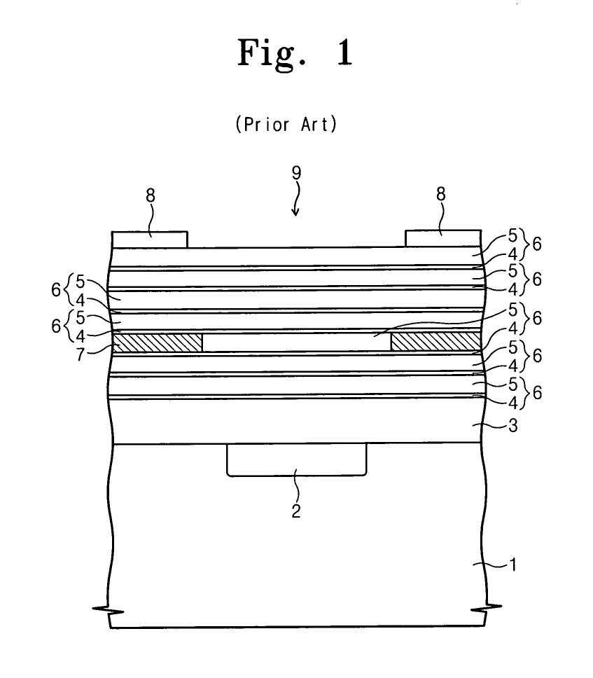

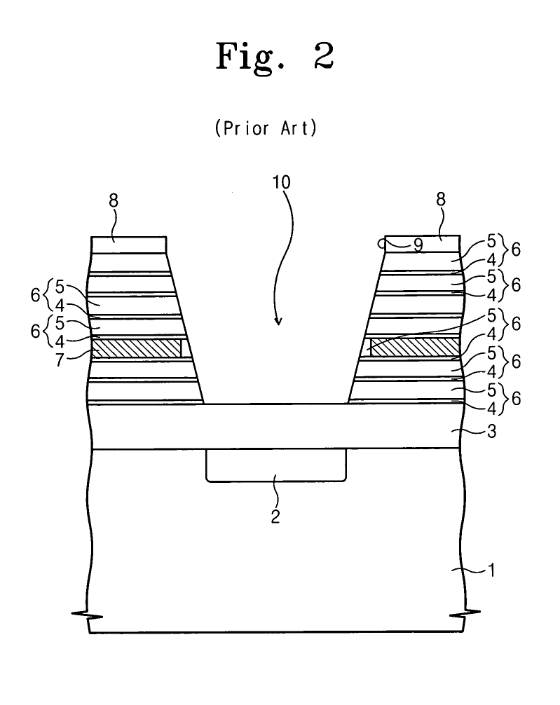

### DETAILED DESCRIPTION OF THE EXEMPLARY EMBODIMENTS OF THE INVENTION

The present invention will now be described more fully with reference to the accompanying drawings, in which exemplary embodiments of the invention are shown. The invention may, however, be embodied in many different forms and should not be construed as being limited to the embodiments set forth herein. In the drawings, the thicknesses of layers and regions are exaggerated for clarity. In addition, it will also be understood that when a layer is referred to as being “on” another layer or substrate, it can be directly on the other layer or substrate, or intervening layers may also be present. Like reference numerals in the drawings denote like elements, and thus their description will be omitted.

### First Exemplary Embodiment

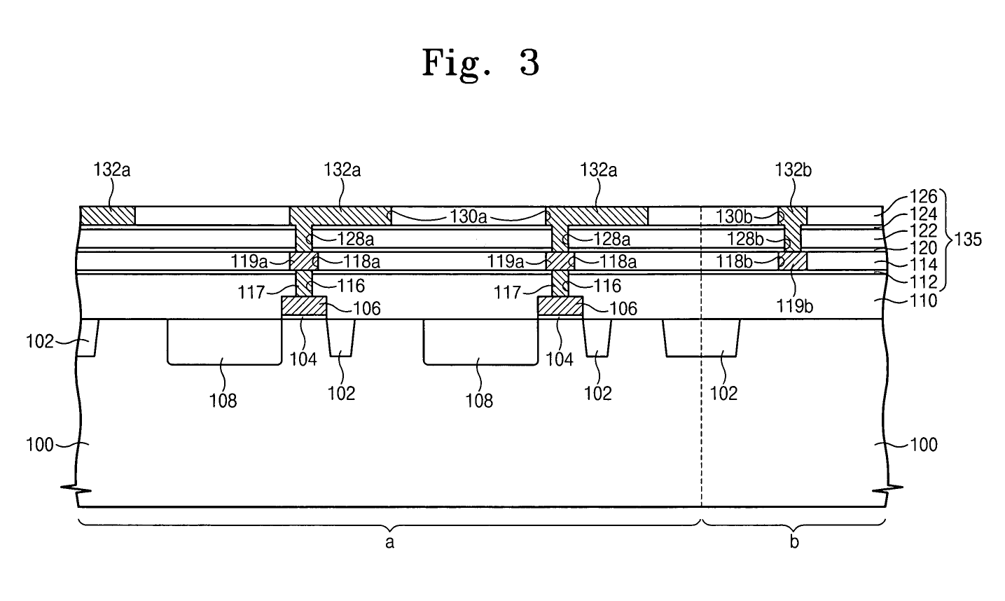

FIGS. 3 to 9 are cross-sectional views illustrating a method of forming an image sensor according to a first exemplary embodiment of the present invention.

Referring to FIG. 3, a semiconductor substrate 100 has a pixel region a and a peripheral region b. The pixel region a is a region in which pixels of the image sensor are formed, and the peripheral region b is a region in which peripheral circuits of the image sensor are formed. The semiconductor substrate 100 of the pixel region a is doped with first conductive impurities. Moreover in this exemplary embodiment, the semiconductor substrate 100 may be doped by forming a well doped with the first conductive impurities in the semiconductor substrate 100 of the pixel region a.

An isolation layer 102 is formed in a predetermined region of the semiconductor substrate 100. The isolation layer 102 defines a plurality of active regions in the pixel region a. Additionally, the isolation layer 102 also defines peripheral active regions in the peripheral region b. Upon the pixel active region, a gate insulating layer 104 and a gate electrode 106 are formed in sequence. The gate electrode 106 constitutes a transistor in the pixel of the CMOS image sensor. Also, a peripheral gate electrode may be formed in the peripheral region b while forming the gate electrode 106.

Second conductive impurity ions are selectively injected into the pixel active region at one side of the gate electrode 106 to form an impurity diffusion layer 108. The impurity diffusion layer 108 constructs a p-n junction with the semiconductor substrate 100 having the first conductive ions, to thereby form a photodiode. The impurity diffusion layer 108 is formed in each of the pixel active regions. Therefore, a plurality of impurity diffusion layers 108 are formed in the pixel region a, wherein the impurity diffusion layers 108 are spaced apart from one another. In other words, in the pixel region a, a plurality of photodiodes are spaced apart from one another.

The second conductive impurity ions may be injected into the pixel active region at the other side of the gate electrode 106, to thereby form a floating diffusion layer. The impurity diffusion region 108 and the floating diffusion layer may correspond to source/drain regions of a MOS transistor. The impurity diffusion layer 108 and the floating diffusion layer may also be formed at different depths from one another.

The first conductive impurities are different from the second conductive impurities. For instance, the first conductive impurities may be n-type impurities and the second conductive impurities may be p-type impurities. On the contrary, the first conductive impurities may be p-type impurities and the second conductive impurities may be n-type impurities.

Further, a surface diffusion layer doped with the first conductive impurities may be formed on a surface of the impurity diffusion layer 108. The surface diffusion layer may minimize a dark current which may occur due to a surface condition, e.g., dangling bonds or the like, of the semiconductor substrate 100 where the diffusion layer 108 is formed. The surface diffusion layer is electrically connected to the semiconductor substrate 100. In addition, gate spacers may be formed on sidewalls of the gate electrode 106.

A protection insulating layer 110 is formed over the semiconductor substrate 100 having the impurity diffusion layer 108 and the gate electrode 106. The protection insulating layer 110 acts as a protection layer for the impurity diffusion layer 108 as well as an interlayer insulator. It is preferable to form the protection insulating layer 110 which includes an insulating material having a high light transmissivity. For example, it is preferable to form a protection insulating layer 110 comprised of a silicon oxide layer.

A first barrier insulating layer 112 is formed on the protection insulating layer 110 and then, the first barrier layer 112 and the protection insulating layer 110 are successively patterned, to thereby form a first pixel hole 116 in the pixel region a. The first pixel hole 116 may expose a top surface of the gate electrode 106 as shown in FIG. 3. Moreover, the first pixel hole 116 may expose the semiconductor substrate 100. In forming the first pixel hole 116, a first peripheral hole may be formed exposing a gate electrode formed in the peripheral region b or the semiconductor substrate 100 in the peripheral region b.

A conductive plug 117 is formed to fill the first pixel hole 116. The conductive plug 117 may include polysilicon doped with a conductive material, including but not limited to a conductive nitride such as titanium nitride or tantalum nitride, or tungsten. In forming the conductive plug 117, a conductive plug filling the peripheral hole may be simultaneously formed.

Further, a first interlayer dielectric layer 114 is formed over the semiconductor substrate 1100 having the conductive plug 117. The first interlayer dielectric layer 114 is patterned to form a first pixel groove 118a in the pixel region a and a first peripheral groove 118b in the peripheral region b. The first pixel groove 118a exposes the conductive plug 117 and the first peripheral groove 118b exposes the conductive plug formed in the first peripheral hole.

A first metal layer is formed to fill the first pixel groove 118a and the first peripheral groove 118b and is planarized until the first interlayer dielectric layer 114 is exposed, to thereby form a first pixel metal interconnection 119a in the first pixel groove 118a and a first peripheral metal interconnection 119b in the first peripheral groove 118b. Each of the first pixel metal interconnection 119a and the first peripheral metal interconnection 119b may include copper or aluminum: In addition, the metal interconnections 119a and 119b may further include a conductive barrier encompassing the copper layer or the aluminum layer. Also, the conductive barrier may include titanium nitride or tantalum nitride.

The first pixel metal interconnection 119a is not formed over the impurity diffusion layer 108 but may be formed in the first interlayer dielectric layer 114 disposed between the n-type impurity diffusion layers 108. Herein, the first barrier insulating layer 112 and the first interlayer dielectric layer 114 will be referred to as a first interconnection mold layer for forming the first metal interconnections 119a and 119b.

Over the semiconductor substrate 100 having the interconnections 119a and 119b, a second barrier insulating layer 120, a second interlayer dielectric layer 122, a third barrier insulating layer 124, and a third interlayer dielectric layer 126 are formed. In addition, a second pixel hole 128a and a second peripheral hole 128b are formed which penetrate through the third barrier insulating layer 120, the second interlayer dielectric layer 122 and the second barrier insulating layer 120. Furthermore, a second pixel groove 130a and a second peripheral groove 130b are formed in the third interlayer dielectric layer 126. The second pixel hole 128a and the second pixel groove 130a are formed in the pixel region a. In particular, the second pixel hole 128a and the second pixel groove 130a may be formed between the n-type impurity diffusion layers 108, i.e., the photodiodes. The second peripheral hole 128b and the second peripheral groove 130b are formed in the peripheral region b. The second pixel groove 130a and the second pixel hole 128a communicate with each other and the second peripheral groove 130b and the second peripheral hole 128a communicate with each other.

The second pixel hole 128a may expose the first pixel metal interconnection 119a. Unlike this, the second pixel hole 128a may expose a buffer pattern spaced apart from one side of the first pixel metal interconnection 119a. The buffer pattern is formed to coincide with the first pixel metal interconnection 119a and may be in contact with another gate electrode in the pixel or the semiconductor substrate 100. The second peripheral hole 128b may expose the first peripheral metal interconnection 119b.

After forming the second pixel and peripheral holes 128a and 128b, the second pixel and peripheral grooves may be formed. In other words, the third interlayer dielectric layer 126, the third barrier insulating layer 124, the second interlayer dielectric layer 122 and the second barrier layer 120 are patterned successively so as to form the pixel and peripheral holes 128a and 128b. Afterwards, the second pixel and the peripheral grooves 130a and 130b, which communicate with the second pixel and the peripheral holes 128a and 128b, may be formed by patterning the third interlayer dielectric layer 126.

On the contrary, after forming the second pixel and the peripheral grooves 130a and 130b, the second pixel and the peripheral holes 128a and 128b may be formed. That is, the third interlayer dielectric layer 126 is patterned to form the second pixel and the peripheral grooves 130a and 130b exposing the third barrier insulating layer 124. Thereafter, the exposed third barrier insulating layer 124, the second interlayer dielectric layer 122 and the second barrier insulating layer 120 are successively patterned, to thereby form the second pixel and the peripheral holes 128a and 128b.

A second metal layer is formed over the semiconductor substrate 100 to fill the second pixel and the peripheral grooves 130a and 130b, and the second pixel and the peripheral holes 128a and 128b. The second metal layer is planarized until the third interlayer dielectric layer 126 is exposed to form a second pixel metal interconnection 132a in the second pixel hole 128a and second pixel groove 130a, and a second peripheral metal interconnection 132b in the second peripheral hole 128b and second peripheral groove 130b. The second metal layer may include aluminum or copper. In addition, the second metal layer may further include a conductive barrier encompassing the aluminum layer or the copper layer, wherein the conductive layer, for example, may be a conductive metal nitride such as titanium nitride or tantalum nitride.

The third interlayer dielectric layer 126 in which the second pixel and the peripheral metal interconnections 132a and 132b are formed, the third barrier insulating layer 124, the second interlayer dielectric layer 122 and the second barrier insulating layer 120, are collectively referred to as a second interconnection mold layer. The first and the second interconnection mold layers constitute a lower mold insulating layer 135.

The lower mold insulating layer 135 is defined as an insulating structure wherein the pixel metal interconnections 119a and 132a are formed in the pixel region a. Accordingly, in case that the first and the second pixel metal interconnections 119a and 132 are formed in the pixel region a, the lower mold insulating layer 135 may include the first and the second interconnection mold layers, as described above. Whereas, in case that the pixel metal interconnection having one layer is needed in the pixel, the lower mold insulating layer 135 may include the interconnection mold layer with only one layer. Meanwhile, if there is a need for at least-three-layered pixel metal interconnection in the pixel, the lower mold insulating layer 135 may include the interconnection mold layers with at least three layers.

In other words, the lower mold insulating layer 135 may include the interconnection mold layer with at least one layer. The interconnection mold layer may be formed such that the barrier insulating layer 112 and the interlayer dielectric layer 114 are stacked alternately one time like the first interconnection mold layer. Alternatively, the interconnection mold layer may be formed such that the barrier insulating layers 120 and 124 and the interlayer dielectric layers 122 and 126 are stacked alternately two times like the second interconnection mold layer.

It is preferable that the barrier insulating layers 112, 120 and 124 be formed of an insulating material for preventing diffusion of metal atoms in the metal interconnections 119a, 119b, 132a and 132b. In addition, it is preferable that the barrier insulating layers 112, 120 and 124 have an etching selectivity with respect to the interlayer dielectric layers 114, 122 and 126. For instance, the interlayer dielectric layer 114, 122 and 126 may be formed of a silicon oxide layer and the barrier insulating layer 112, 120 and 124 may be formed of a silicon nitride layer.

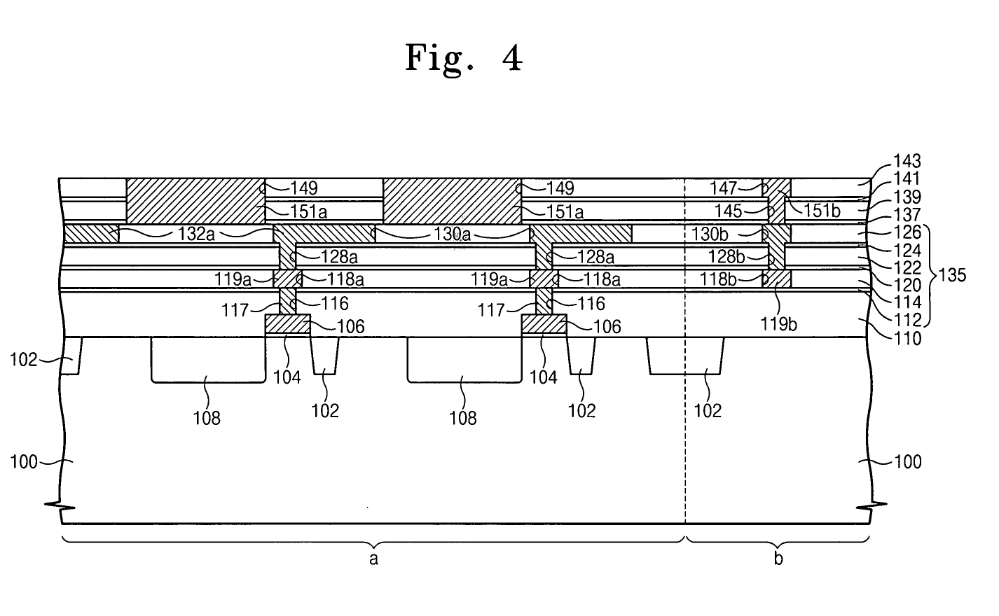

Referring to FIG. 4, a third interconnection mold layer is formed over the semiconductor substrate 100 having the second pixel and the peripheral metal interconnections 132a and 132b. The third interconnection mold layer includes a fourth barrier insulating layer 137, a fourth interlayer dielectric layer 139, a fifth barrier insulating layer 141 and a fifth interlayer dielectric layer 143 which are stacked in sequence.

Moreover, a third peripheral hole 145 is formed penetrating through a third peripheral groove 147 in the fifth interlayer dielectric layer 143, the fifth barrier insulating layer 141, the fourth interlayer dielectric layer 139, and the fourth barrier insulating layer 137. The third peripheral hole 145 and the third peripheral groove 147 are formed in the peripheral region b such that they communicate with each other. At this point, a first dummy opening 149 is formed to expose the lower mold insulating layer 135, which penetrates through the third interconnection layer of the pixel region a. The first dummy opening 149 is formed over the n-type impurity diffusion region 108, i.e., the photodiode.

A method of forming the third peripheral hole 135, the third peripheral groove 147 and the first dummy opening 149 in accordance the present exemplary embodiment will be described herebelow. It is preferable to form the third peripheral groove 147 communicating with the third peripheral hole 145 by patterning the fifth interlayer dielectric layer 143, after forming the first dummy opening 149 of the pixel region a and the third peripheral hole 145 of the peripheral region b wherein the third interconnection mold layer is successively patterned. It is preferable that the first dummy opening 149 be covered with a photoresist pattern during the formation of the third peripheral groove 147.

Alternatively, the third peripheral hole 145 may be formed after the formation of the third peripheral groove 147. In this case, a portion of the first dumpy opening 149, i.e., the portion of the first dummy opening 149 formed in the fifth interlayer dielectric layer 143, may be formed at the same time with the third peripheral groove 147, and the other portion of the first dummy opening 149 may be formed coinciding with the third peripheral hole 145.

A third metal layer is formed to fill the first dummy opening 149, the third peripheral hole 145 and the peripheral groove 147 and is planarized until the third interconnection layer is exposed, to thereby form a first filling pattern 151a filling the first dummy opening 149 and a third peripheral metal interconnection 151b in the third peripheral hole 145 and the third peripheral groove 147. The third metal layer may include aluminum or copper. In addition, the third metal layer may further include a conductive barrier encompassing the aluminum layer or the copper layer, wherein the conductive barrier layer may be a conductive metal nitride such as titanium nitride or tantalum nitride.

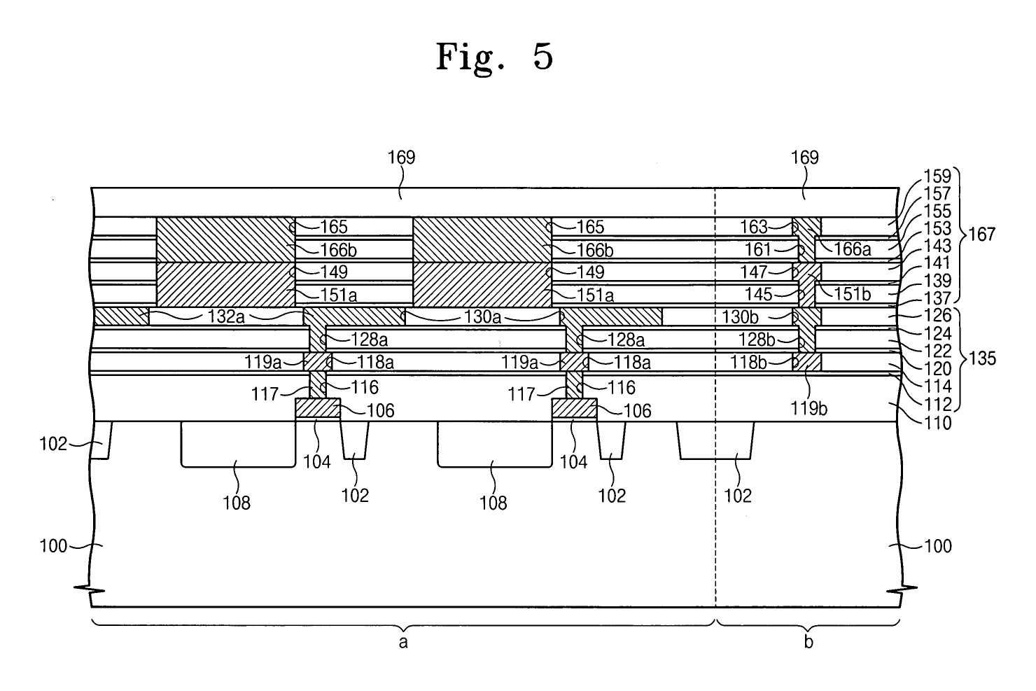

Referring to FIG. 5, a fourth interconnection mold layer is formed over the semiconductor substrate 100 having the first filling pattern 151a and the third peripheral metal interconnection 151b, wherein the fourth interconnection mold layer includes a sixth barrier insulating layer 153, a sixth interlayer dielectric insulating layer 155, a seventh barrier insulating layer 157 and a seventh interlayer dielectric layer 159.

Further, a fourth peripheral hole 161 is formed successively penetrating through a fourth peripheral groove 163 in the seventh interlayer dielectric layer 159, the seventh barrier insulating layer 157, the sixth interlayer dielectric layer 155 and the sixth barrier insulating layer 153 to expose the third peripheral metal interconnection 151b. At this time, in the fourth interconnection mold layer of the pixel region a, a second dummy opening 165 exposing the first filling pattern 151a is formed. The fourth peripheral groove 163 communicates with the fourth peripheral hole 161.

A method of forming the fourth peripheral hole 161, the fourth peripheral groove 163 and the second dummy opening 165 in accordance with the present exemplary embodiment will be described herebelow. It is preferable to form the fourth peripheral groove 163 communicating with the fourth peripheral hole 161 by patterning the seventh interlayer dielectric layer 159, after forming the second dummy opening 165 of the pixel region a and the fourth peripheral hole 161 of the peripheral region b by successively patterning the fourth interconnection mold layer. It is also preferable that the second dummy opening 165 be covered with a photoresist pattern while forming the fourth peripheral groove 163.

According to another method in accordance with the present exemplary embodiment, after forming a portion of the second dummy opening 165 in the fourth peripheral groove 163 in the pixel region a by patterning the seventh interlayer dielectric layer 159, the fourth peripheral hole 161 may be formed by successively patterning the seventh barrier insulating layer 157 exposed to the fourth peripheral groove 163, the sixth interlayer dielectric layer 155 and the sixth barrier insulating layer 153. At this point, the other portion of the second dummy opening 165 is formed at the same time with the fourth peripheral hole 161.

A fourth metal layer is formed over the semiconductor substrate 100 to fill the second dummy opening 165, the fourth peripheral hole 161 and the fourth peripheral groove 163. Thereafter, the fourth metal layer is planarized until the fourth interconnection mold layer is exposed so as to form a second filling pattern 166b filling the second dummy opening 165, and a fourth peripheral metal interconnection 166a filling the fourth peripheral hole 161 and the fourth peripheral groove 163. The second filling pattern 166b is in contact with the first filling pattern 151a. The fourth metal layer may include aluminum or copper. In addition, the fourth metal layer may further include a conductive barrier encompassing the aluminum layer or the copper layer, wherein the conductive layer, for example, may be a conductive metal nitride such as titanium nitride or tantalum nitride.

The third and the fourth interconnection mold layers constitute an upper mold insulating layer 167, and the first and the second filling patterns 151a and 166b constitute a dummy pattern. That is, the upper mold insulating layer 167 includes the interconnection mold layers formed over the pixel metal interconnections 119a and 132a. The dummy pattern is formed in the upper mold insulating layer 167 so as to be in contact with the lower mold insulating layer 135.

Although it is shown that each of the peripheral metal interconnections 151b and 166a having two layers therein is formed in the upper mold insulating layer 167, the peripheral metal interconnection may be formed with one layer or more layers in the upper mold insulating layer 167. That is, the upper mold insulating layer 167 includes the interconnection mold layer with at least one layer in which the peripheral metal interconnection is formed. At this point, the stacked number of the filling patterns is equal to the stacked number of the peripheral metal interconnections. Namely, the dummy pattern includes the filling patterns stacked in a predetermined number of layers equal to the stacked number of the peripheral metal interconnections.

It is preferable that the barrier insulating layers 112, 120, 124, 137, 141, 153 and 157 be formed of the same material. It is also preferable that the interlayer dielectric layers 114, 122, 126, 139, 143, 155 and 159 be formed of the same material.

As described above, each of the lower and the upper mold insulating layers 135 and 167 is a multilayer in which the barrier insulating layers and the interlayer dielectric layers are alternately formed. Herein, it is preferable that the number of the layers contained in the upper mold insulating layer 167 be more than the number of the layers contained in the lower mold insulating layer 135. In detail, it is preferable that the number of the interconnection mold layer contained in the upper mold insulating layer 167 be equal to or more than the number of the interconnection mold layer contained in the lower mold insulating layer 135. In case that each of the lower and the upper mold insulating layers 135 and 167 have the interconnection mold layer with one layer respectively, the interconnection mold layer of the lower mold insulating layer 135 is formed such that the barrier insulating layer 112 and the interlayer dielectric layer 114 are stacked alternately one time, whereas the interconnection mold layer of the upper mold insulating layer 167 is formed such that the barrier insulating layers 137 and 141 and the interlayer dielectric layers 139 and 143 are stacked alternately two times.

A mask layer 169 is formed over the semiconductor substrate 100 having the second filling pattern 166b and the fourth peripheral metal interconnection 166a. The mask layer 169 may be a passivation layer. The mask layer 169 may have an etch selectivity with respect to the lower and the upper mold insulating layers 135 and 167. Furthermore, the mask layer 169 may be formed of sufficient thickness so that it may be used as an etch mask for the lower and the upper mold insulating layers 135 and 167. For instance, the mask layer 169 may be formed of silicon oxynitride or the like.

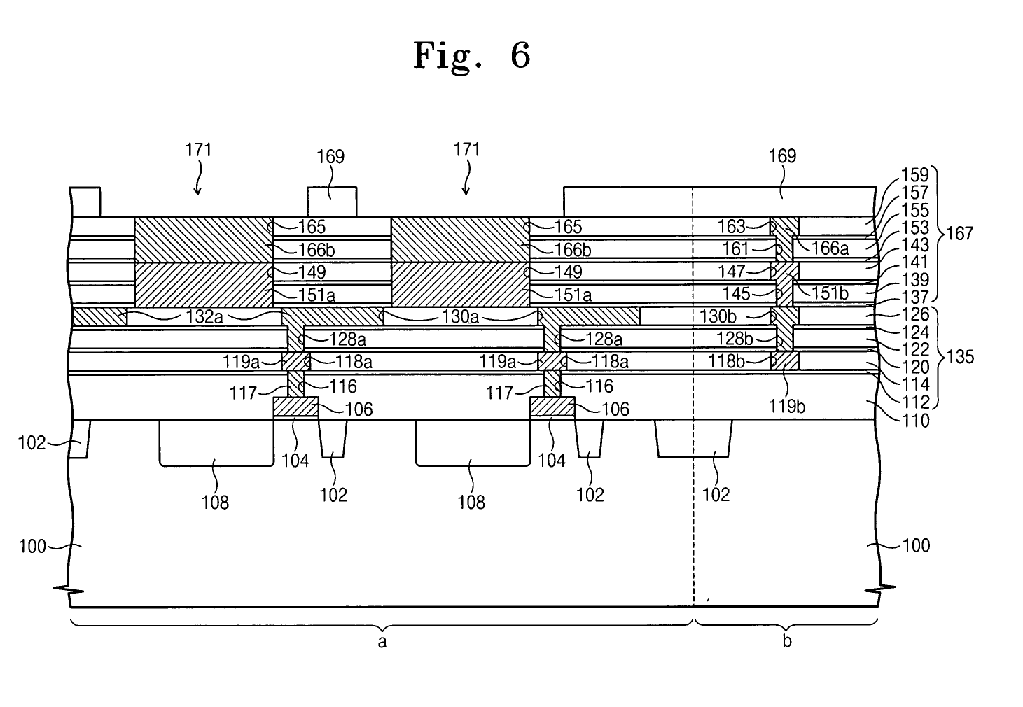

Referring to FIG. 6, the mask layer 169 is patterned to form an opening 171 exposing the dummy pattern. At this point, it is preferable that the width of the opening 171 be greater than the width of the dummy pattern, i.e., the filling patterns 166b and 151b. It is preferable that the width of the patterned mask layer 169 disposed between the n-type impurity diffusion layers 108 be less than the width of the upper mold insulating layer 167 disposed between the n-type impurity diffusion layers 108. That is, the opening 171 exposes edges of the top surface of the upper mold insulating layer 167 disposed between the n-type impurity diffusion layers 108.

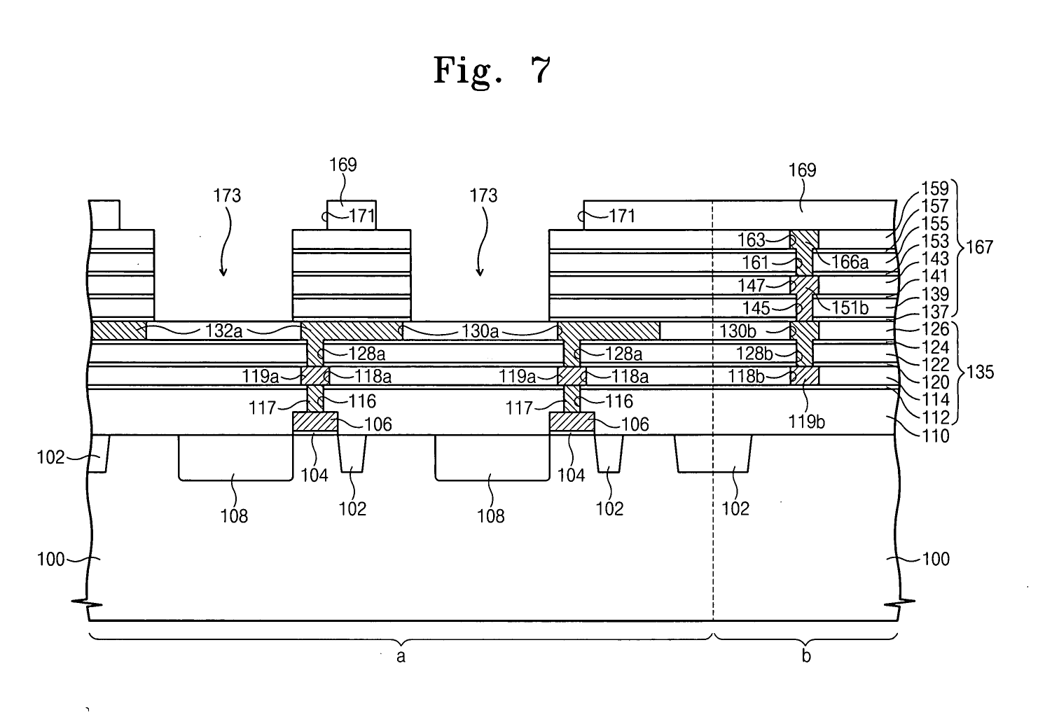

Referring to FIG. 7, the exposed dummy pattern is selectively removed to thereby form a preliminary cavity 173 exposing the lower mold insulating layer 135. It is preferable to remove the dummy pattern by a wet etch. As the dummy pattern is formed of the same metal with the third and the fourth peripheral metal interconnections 151b and 166b, it may be selectively removed.

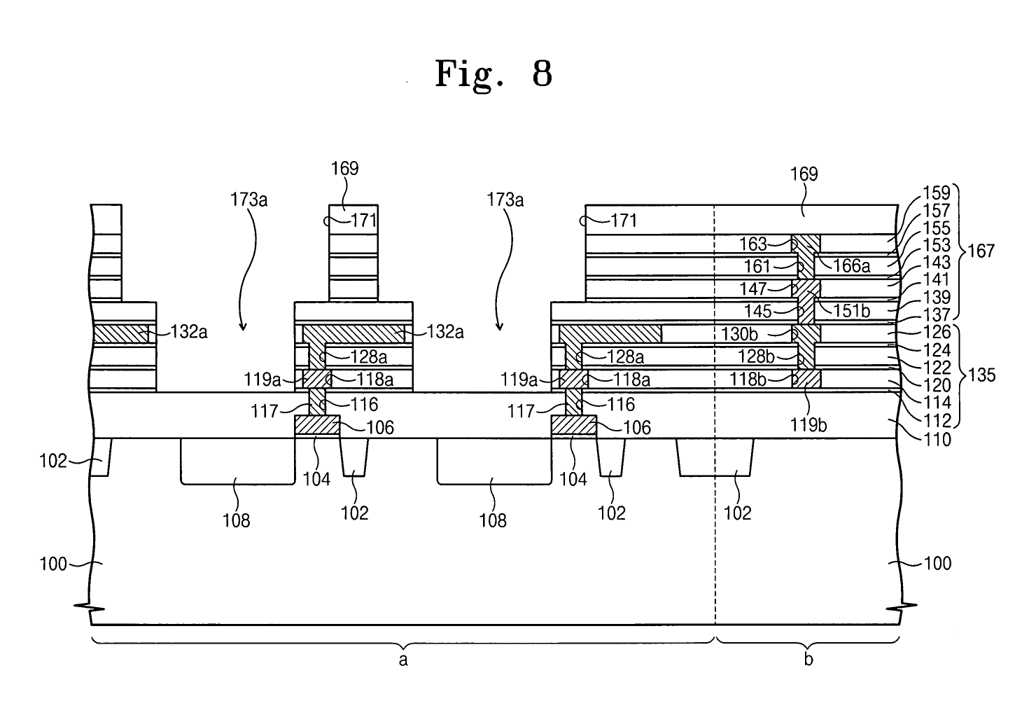

Referring to FIG. 8, the exposed lower mold insulating layer 135 is anisotropically etched using the mask layer 169 having the opening 171 therein as the etch mask, to thereby form a cavity 173a exposing the protection insulating layer 110 disposed over the n-type impurity diffusion layer. At this point, the edges of the upper mold insulating layer 167 disposed between the n-type impurity diffusion layers 108, which are exposed to the opening 171, are also etched concurrently. In each of the upper and the lower mold insulating layers 167 and 135, the barrier layer and the interlayer dielectric layer are alternately stacked a plurality of times. Accordingly, when the lower mold insulating layer 135 is anisotropically etched, the edges of the upper mold insulating layer 167 is anisotropically etched concurrently. As a result, the cavity 173a in the upper mold insulating layer 167 is formed such that it has a predetermined width greater than that of the cavity 173a in the lower mold insulating layer 135.

In the anisotropic etch, it is preferable that a lower portion of the upper mold insulating layer 167 cover the lower mold insulating layer 135 disposed thereunder. The number of the insulating layers contained in the upper mold insulating layer 167 is larger than that of the lower mold insulating layer 167. Accordingly, the lower portion of the upper mold insulating layer 167 may remain. The remaining lower portion of the upper mold insulating layer 167 covers the second pixel metal interconnection 132a formed thereunder. In particular, as the top surface of the second pixel metal interconnection 132a is identical to the top surface of the lower mold insulating layer 135, the remaining lower portion of the upper mold insulating layer 167 is in contact with the second metal interconnection 132a. A bottom surface of the upper mold insulating layer 167 is formed of the barrier insulating layer 137 so that it is possible to prevent diffusion of metal atoms in the second pixel metal interconnection 132a.

As the barrier insulating layers 112, 120, 124, 137, 141, 153 and 157 are formed of the same material and the interlayer dielectric layers 114, 122, 126, 139, 143, 155 and 159 are also formed of the same material, the insulating layers in the portion of the upper mold insulating layer 167 anisotropically etched are formed of the same material with insulating layers in the lower mold insulating layer 135 and are stacked in the same sequence with the stacking sequence of the insulating layers of the lower mold insulating layer 135.

It is not required that the barrier insulating layers 112, 120, 124, 137, 141, 153 and 157 be formed with the same thickness as one another. Further, it is not required that the interlayer dielectric layers 114, 122, 126, 139, 143, 155 and 159 be formed with the same thickness as one another. Each of the barrier insulating layers 112, 120, 124, 137, 141, 153 and 157 and each of the interlayer dielectric layers 114, 122, 126, 139, 143, 155 and 159 act as the etch stop layer in the anisotropic etch by virtue of etching selectivity.

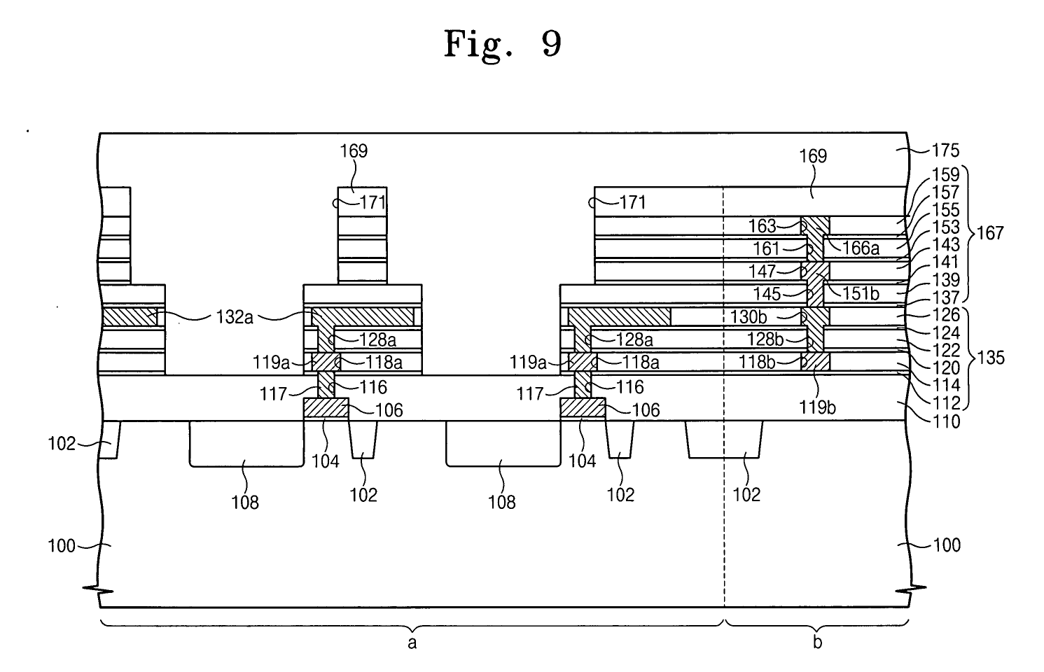

Referring to FIG. 9, a transparent insulating layer 175 is formed over the semiconductor substrate 100 to fill the cavity 173a. The transparent insulating layer 175 is formed of an insulating material having a high light transmissivity. The transparent insulating layer may be formed by a spin coating type method.

According to the method of forming the image sensor as described above, after forming the preliminary cavity 173 by removing the dummy pattern formed in the upper mold insulating layer 167, the cavity 173a is formed by anisotropically etching the lower mold insulating layer 135 exposed to the preliminary cavity 173. That is, the anisotropic etch depth for forming the cavity 173a becomes significantly reduced in comparison with the conventional art. Accordingly, the width of the lower portion of the cavity 173a defines the top surface of the n-type impurity diffusion region 108 and further, the width of the upper portion of the cavity 173a is greater than that of the lower portion of the cavity 173a. Accordingly, it is possible for the photodiode to receive much more external light, which results in the intensity of the light incident on the photodiode increasing, thereby enhancing the photosensitivity of the image sensor.

### Second Examplary Embodiment

The second exemplary embodiment is similar to the first exemplary embodiment as aforementioned. Therefore, like reference numerals in the second exemplary embodiment denote like elements in the first exemplary embodiment. A method of forming the image sensor according to the second exemplary embodiment may include the same method described with reference to FIGS. 3 to 5 of the first exemplary embodiment.

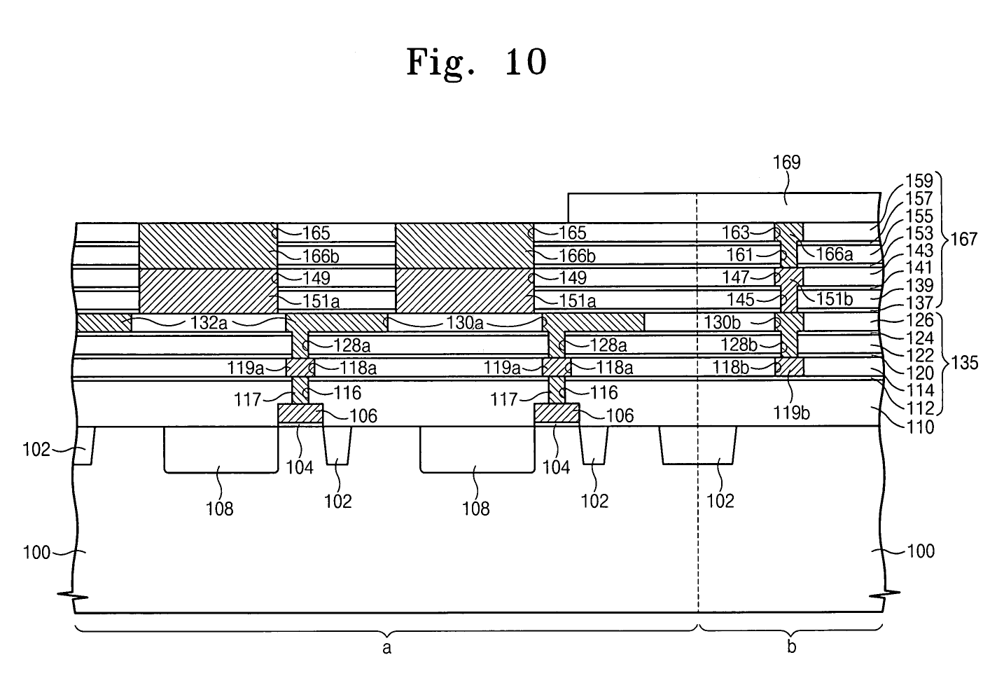

FIGS. 10 to 13 are cross-sectional views illustrating a method of forming the image sensor according to the second exemplary embodiment of the present invention.

Referring to FIGS. 5 and 10, the mask layer 169 is formed over the semiconductor substrate 100 having the second filling pattern 166b and the fourth peripheral metal interconnection 166a, and is patterned to expose the dummy pattern. At this time, the upper mold insulating layer 167 disposed between the n-type impurity diffusion layers 108 is exposed. That is, the mask layer 169 over the pixel region a is removed except a portion of the mask layer 169 disposed near a boundary between the pixel region a and the peripheral region b. The patterned mask layer 169 covers the fourth peripheral metal interconnection 166a of the peripheral region b.

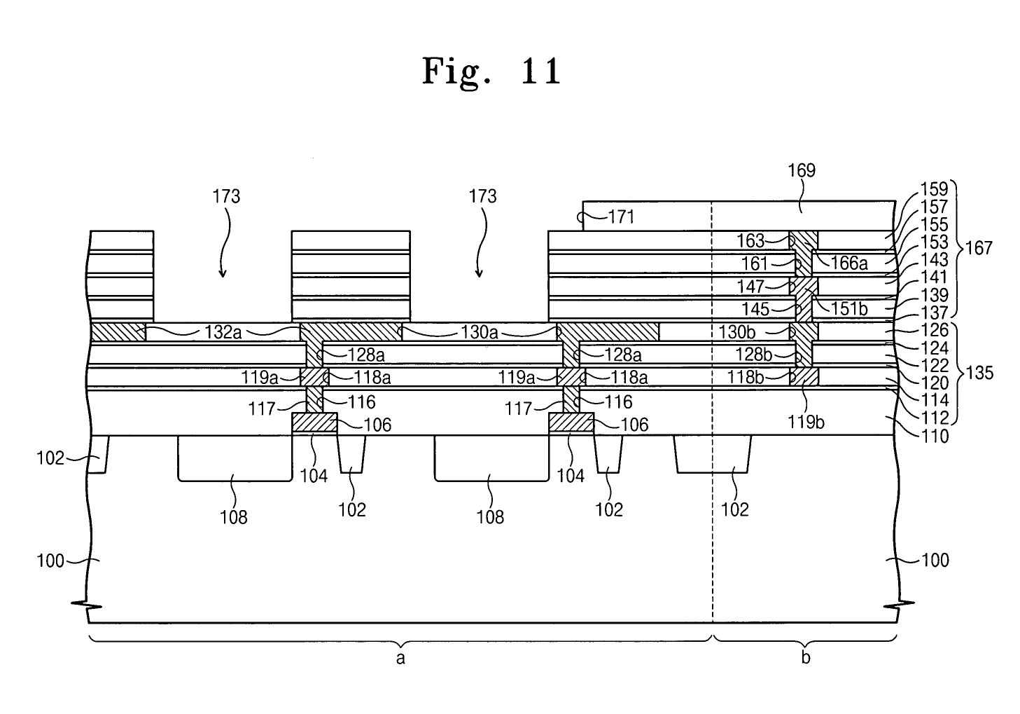

Referring to FIG. 11, the dummy pattern is selectively removed to form the preliminary cavity 173 exposing the lower mold insulating layer 135. It is preferable that the dummy pattern be removed by the wet etch, as illustrated in the first exemplary embodiment.

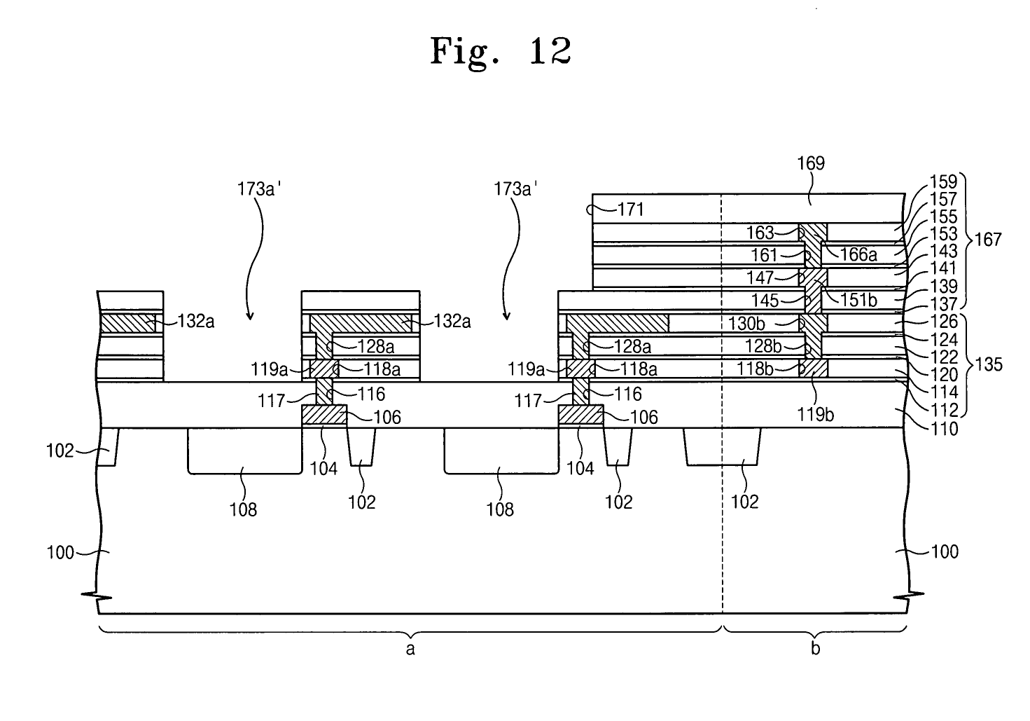

Referring to FIG. 12, the exposed lower mold insulating layer 135 is anisotropically etched using the patterned mask layer as the etch mask, to thereby form the cavity 173a′ exposing the protection insulating layer 110 over the n-type impurity diffusion layer 108. At this time, the top surface of the upper mold insulating layer 167 disposed between the n-type impurity diffusion layers 108. Accordingly, the upper portions of the neighboring cavities 173a′ are formed to communicate with each other.

It is preferable that the lower portion of the upper mold insulating layer 167 disposed between the n-type impurity diffusion layers 108 remain. Accordingly, the remaining lower portion of the upper mold insulating layer 167 covers the lower mold insulating layer 167 disposed between the n-type impurity diffusion layers 108. The bottom layer of the upper mold insulating layer 167 is formed as the barrier insulating layer 137 which is able to prevent the diffusion of the metal atoms in the second pixel metal interconnection 132a. As a result, the second pixel metal interconnection 132a is in contact with the upper mold insulating layer 167 so as to prevent the diffusion of the metal atoms in the second pixel metal interconnection 132a.

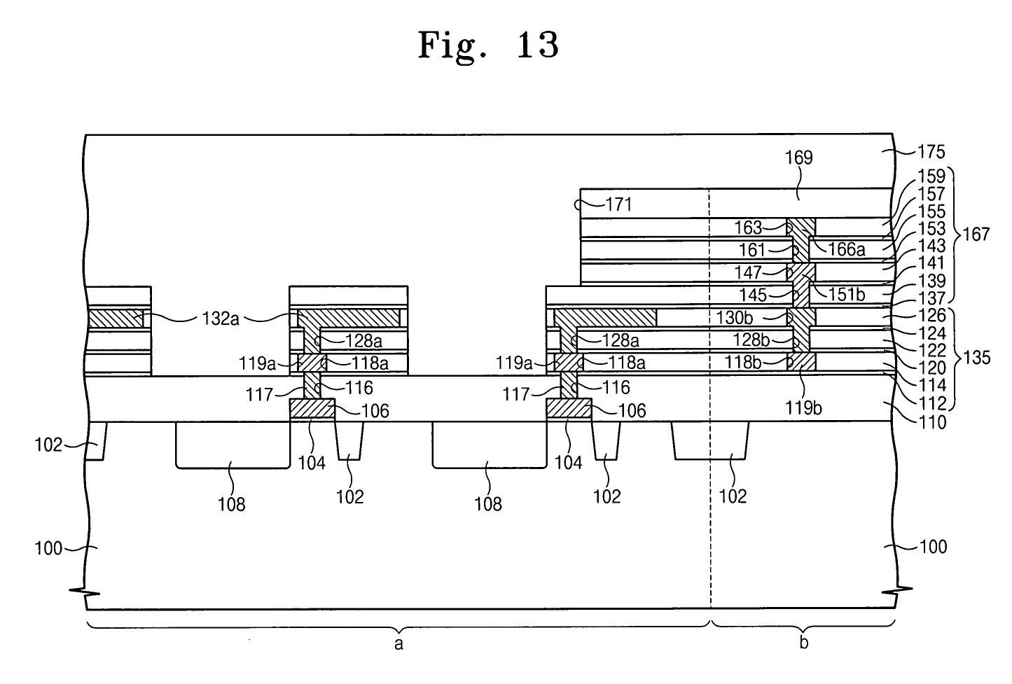

Referring to FIG. 13, the transparent insulating layer 175 filling the cavities 173a′ is formed over the semiconductor substrate 100.

According to the method of forming the image sensor as described above, the upper mold insulating layer 167 disposed between the n-type impurity diffusion layers 108, i.e., the photodiodes, is etched with the anisotropic etch. As a result, the upper portions of the cavities 173a′ are formed to communicate with each other so as to enhance the intensity of the external light incident on the photodiode, i.e., the n-type impurity region 108. Consequently, the photosensitivity of the image sensor is improved.

### Third Exemplary Embodiment

In the third exemplary embodiment, a method of forming the image sensor capable of preventing crosstalk between adjacent photodiodes as well as improving the photosensitivity of the image sensor is provided. This exemplary embodiment is similar to the second exemplary embodiment, and thus like reference numerals of the third exemplary embodiment denote like elements in the first embodiment. The method of the third exemplary embodiment may include the method illustrated in FIG. 3 of the first exemplary embodiment.

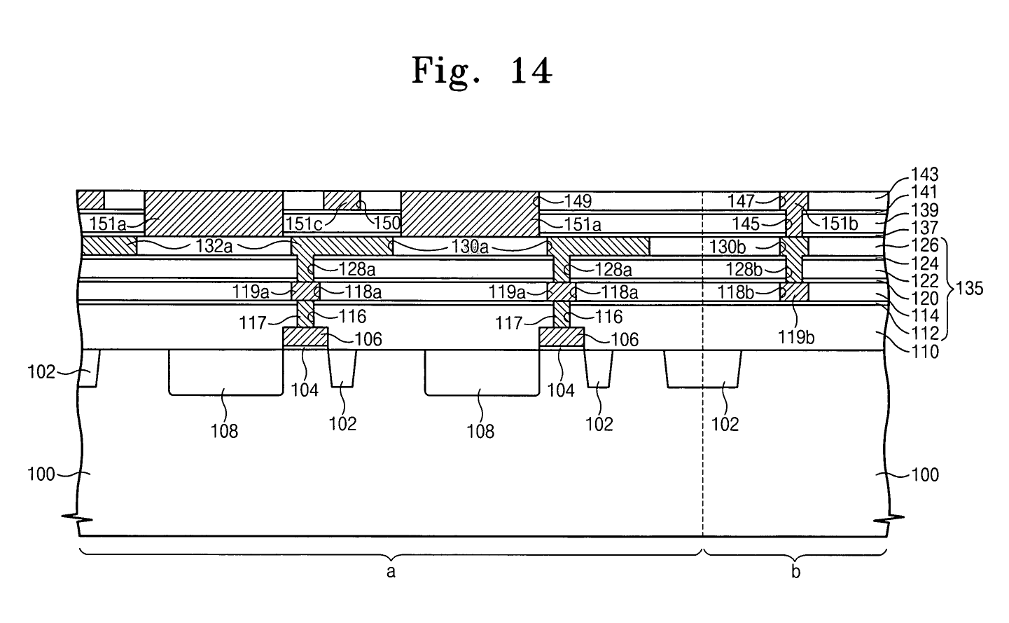

FIGS. 14 to 17 are cross-sectional views illustrating a method of forming the image sensor according to the third exemplary embodiment of the present invention.

Referring to FIGS. 3 and 14, a third interconnection mold layer is formed over the semiconductor substrate 100 having the second pixel and peripheral metal interconnections 119a and 119b. The third interconnection mold layer includes a fourth barrier insulating layer 137, a fourth interlayer dielectric layer 139, a fifth barrier insulating layer 141 and a fifth interlayer dielectric layer 143 stacked in sequence.

A third peripheral hole 145, a third peripheral groove 147 communicating with the third peripheral hole 145, a first dummy opening 149 and a first crosstalk prevention groove 150 are formed. It is preferable that the first crosstalk prevention groove be formed coinciding with the third peripheral grove 147. That is, it is preferable that the first crosstalk prevention groove 150 be formed in the fifth interlayer dielectric layer 143. The first crosstalk prevention groove 150 exposes the fifth barrier insulating layer 141, wherein the bottom surface of the first crosstalk prevention groove 150 is spaced apart from the lower mold insulating layer 135.

A third metal layer is formed over the semiconductor substrate 100 to fill the first dummy opening 149, the first cross protection groove 150, the third peripheral hole 145 and the third groove 147. The third metal layer may include the same material used in the first exemplary embodiment. The third metal layer is planarized until the third interconnection mold layer, i.e., the fifth interlayer dielectric layer 143, is exposed, to thereby form a first filling pattern 151a filling the first dummy opening 149, a third filling pattern 151a filling the third peripheral hole 145 and the third peripheral groove 147, and a first crosstalk prevention pattern 151c filling the first crosstalk prevention groove 150. The first crosstalk prevention pattern 151c is upwardly spaced apart from the lower mold insulating layer 135.

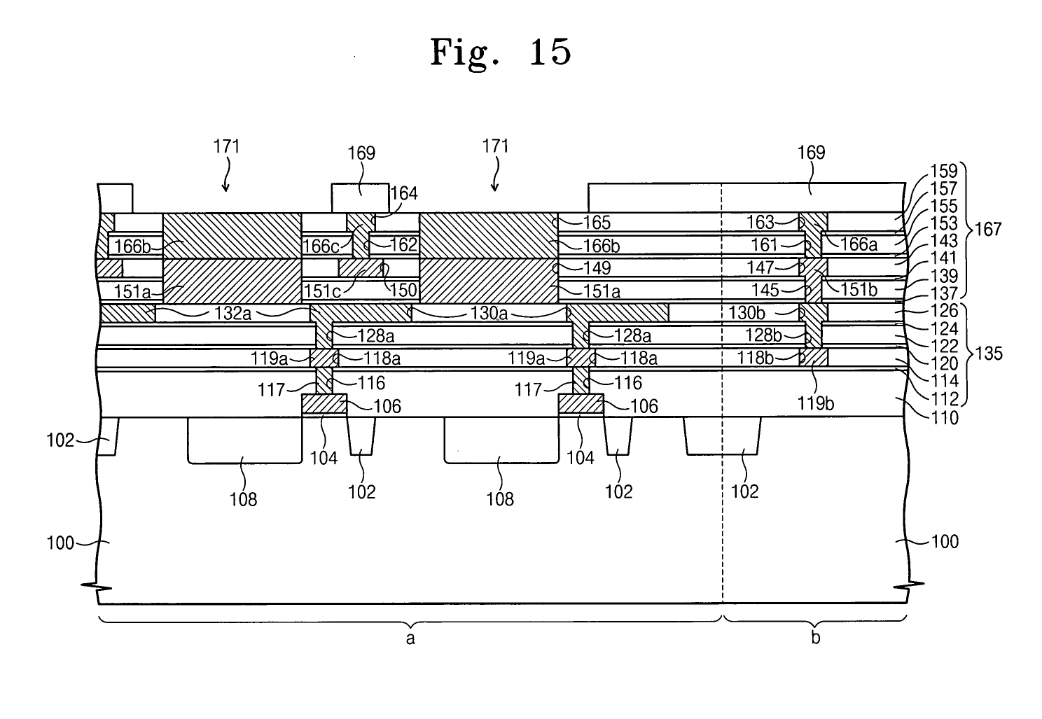

Referring to FIG. 15, a fourth interconnection mold layer is formed over the semiconductor substrate 100, in which a sixth barrier insulating layer 153, a sixth interlayer dielectric layer 155, a seventh barrier insulating layer 157 and a seventh interlayer dielectric layer 159 are stacked in sequence.

In the fourth interconnection mold layer, a second dummy opening 165, a fourth peripheral hole 161, a fourth peripheral groove 163, a contact groove 162, and a second crosstalk prevention groove 164 are formed. It is preferable that the contact groove 162 be simultaneously formed with the fourth peripheral hole 161 and the second crosstalk prevention groove 164 be simultaneously formed with the fourth peripheral groove 163. That is, the contact groove 162 penetrates through the seventh barrier insulating layer 157, the sixth interlayer dielectric layer 155 and the sixth barrier insulating layer 153 in sequence to expose the first crosstalk prevention pattern 151c. The second crosstalk prevention groove 164 is formed in the seventh interlayer dielectric layer 159 so that it communicates with the contact groove 162. The contact and the second crosstalk prevention grooves 162 and 164 pass through between the n-type impurity diffusion layers 108.

A fourth metal layer is formed to fill the second dummy opening 165, the contact groove 162, the second crosstalk prevention groove 164, the fourth peripheral hole 161 and the fourth peripheral groove 163. The fourth metal layer may include the same material used in the first exemplary embodiment as described above. The fourth metal layer is planarized until the fourth interconnection mold layer is exposed, thereby forming a fourth peripheral metal interconnection 166a filling the fourth peripheral hole 161 and the fourth peripheral groove 163, a second filling pattern 166b filling the second dummy opening 165, and the second crosstalk prevention pattern 166c filling the second crosstalk prevention groove 164.

The first and the second crosstalk prevention patterns 151c and 166c construct the crosstalk prevention barrier. The crosstalk prevention barrier includes the crosstalk prevention patterns 151c and 166c of which the stacked number is equal to that of the filling patterns 151a and 166b. At this time, it is preferable that the lowermost layer of the crosstalk prevention pattern 151c be spaced apart from the lower mold insulating layer 167.

A mask layer is formed over the semiconductor substrate 100 having the crosstalk prevention barrier and the dummy pattern. The mask layer 169 is patterned to form an opening 171 exposing the dummy pattern. At this time, the patterned mask layer 169 disposed between the n-type impurity diffusion layers 108 covers the crosstalk prevention barrier. Also, the opening has a large width in comparison with the dummy pattern. That is, it is preferable that the width of the patterned mask layer 169 disposed between the n-type impurity diffusion layers 108 be less than the width of the upper mold insulating layer 167 disposed between the n-type impurity diffusion layer 108.

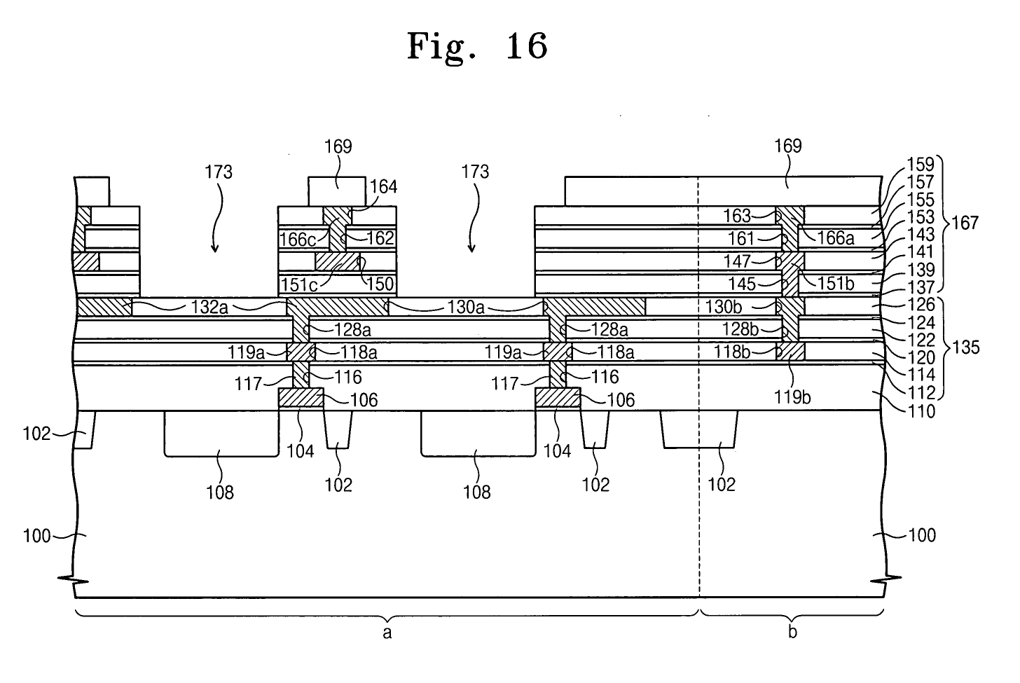

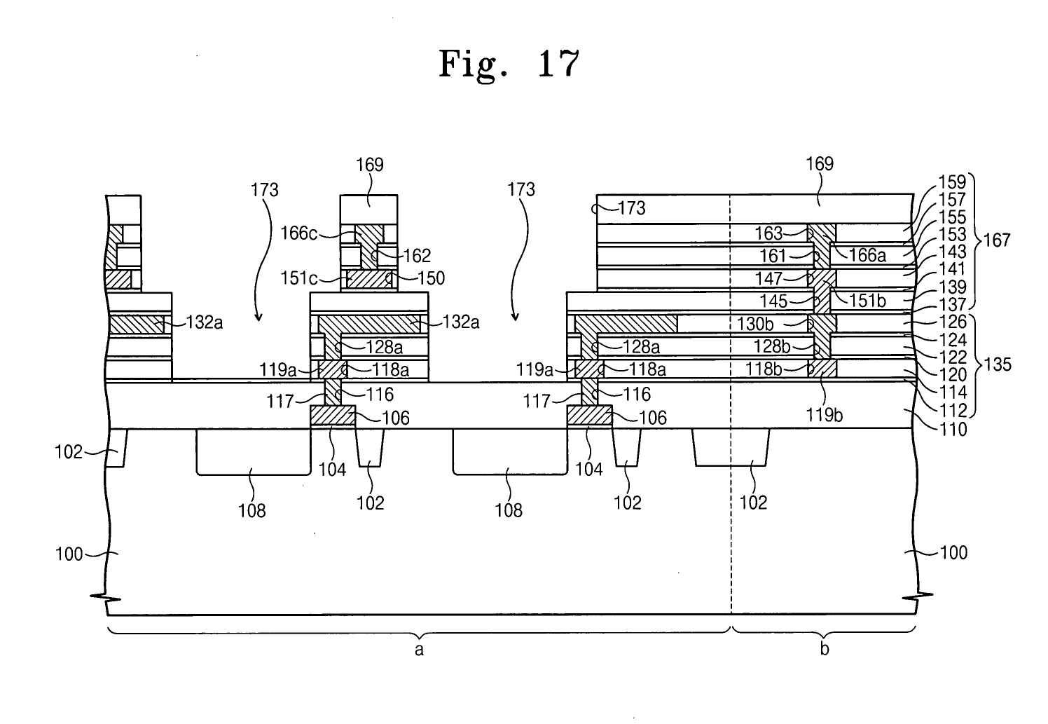

Referring to FIGS. 16 and 17, the exposed dummy pattern is selectively removed to form the preliminary cavity exposing the upper mold insulating layer 135. It is preferable to remove the dummy pattern by the wet etch. The exposed lower mold insulating layer 135 is anisotropically etched using the patterned mask layer as the etch mask, to thereby form a cavity 173a exposing the protection insulating layer 110 over the n-type impurity diffusion layer 108. At this point, the edges of the upper mold insulating layer 167 disposed between the n-type impurity diffusion layers 108 exposed to the opening 171 are also etched during the anisotropic etch. It is preferable that the lower portion of the upper mold insulating layer 167 remain in the anisotropic etch. The other portion of the upper mold insulating layer 167 may perform the same function as mentioned in the first exemplary embodiment and may include the same material used in the first exemplary embodiment.

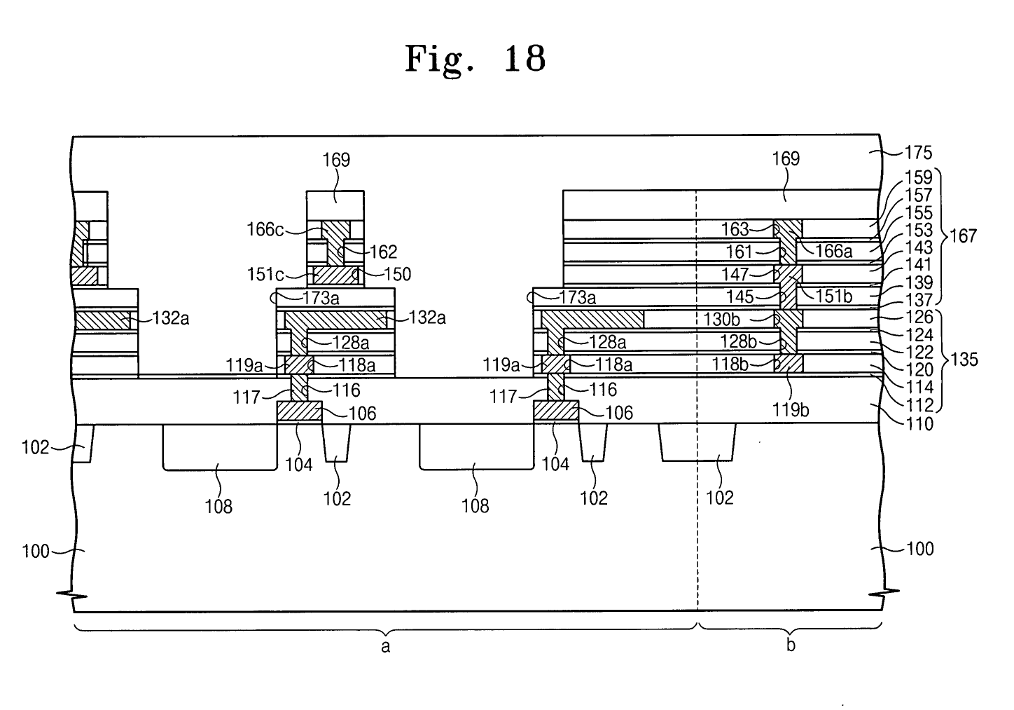

Thereafter, a transparent insulating layer 175 of FIG. 18 is formed to fill the cavity 173a.

According to the method of forming the image sensor as described above, the cavity 173a is formed by performing the anisotropic etch after removing the dummy pattern selectively. Accordingly, it is possible to form sidewalls of the cavity 173a almost vertically. As a result, it is possible to maximally secure an open region of the photodiode and enhance the alignment margin. In addition, since the edges of the upper mold insulating layer 167 disposed between the n-type impurity diffusion layers 108 are also etched in the anisotropic etch, it is possible to increase the width of the upper portion of the cavity 173a while maintaining the width of the lower portion thereof. Consequently, the quantity of the incident light increases thereby improving the photosensitivity of the image sensor. In addition, the crosstalk prevention barrier is formed in the upper mold insulating layer 167 disposed between the n-type impurity diffusion layers 108, thereby, minimizing the signal distortion of the pixel by preventing interference with the light incident on the pixels.

Next, an image sensor of an exemplary embodiment of the present invention will be illustrated with reference to FIG. 18.

FIG. 18 is a cross-sectional view illustrating an image sensor according to an exemplary embodiment of the present invention.

Referring to FIG. 18, an isolation layer is arranged in a semiconductor substrate 100 having a pixel region a and a peripheral region b so as to define a plurality of pixel active regions in the pixel region a and define a peripheral active region in the peripheral region b. The semiconductor substrate of the pixel region a is doped with first conductive impurities.

A gate insulating layer 104 and a gate electrode 106 are stacked in sequence on the pixel active region. An impurity diffusion layer 108 doped with second impurities is arranged in the pixel active region at one side of the gate electrode 106. The impurity diffusion layer 108 constructs a p-n junction with the semiconductor substrate 100 to form a photodiode.

A protection insulating layer 110 covers the semiconductor substrate 100. A lower mold insulating layer 135 and an upper mold insulating layer 167 are stacked in sequence on the protection insulating layer 110. A cavity 173a successively penetrates through the upper and the lower mold insulating layers 167 and 135. It is preferable that the width of the cavity 173a formed in the upper mold insulating layer 167 be less than the width of the cavity 173a formed in the lower mold insulating layer 135.

In the lower mold insulating layer 135 disposed between the n-type impurity diffusion layers 108, pixel metal interconnections 119a and 132a are arranged, wherein each of the pixel metal interconnections 119a and 132a is configured with at least one layer. The pixel metal interconnections 119a and 132a are formed in the interconnection mold layers, respectively. In the drawings, the first pixel metal interconnection 119a and the second pixel metal interconnection 132a are illustrated. The first and the second pixel metal interconnections 119a and 132a are arranged in the first and the second interconnection mold layers, respectively. The first interconnection mold layer includes a first barrier insulating layer 112 and a first interlayer dielectric layer 114 stacked in sequence, and the second interconnection mold layer includes a second barrier insulating layer 120, a second interlayer dielectric layer 122, a third barrier insulating layer 124 and a third interlayer dielectric layer 126. A first peripheral metal interconnection 119b is arranged in the first interconnection mold layer of the peripheral region b and a second peripheral metal interconnection 132b is arranged in the second interconnection mold layer of the peripheral region b.

The lower mold insulating layer 135, the pixel metal interconnections 119a and 132a, and the peripheral metal interconnections 119b and 132b may be formed in the shapes described in FIG. 3.

A crosstalk prevention barrier is formed in the upper mold insulating layer 167 interposed between the n-type impurity diffusion layers 108. The crosstalk prevention barrier includes crosstalk prevention patterns 151c and 166c, wherein each of the crosstalk prevention patterns 151c and 166c is configured with at least one layer. It is preferable that the crosstalk prevention barrier be spaced apart from the lower mold insulating layer 135.

Upon the crosstalk prevention barrier, a patterned mask layer 169 is arranged. It is preferable that the mask layer 169 be a predetermined material having an etching selectivity with respect to the upper and the lower mold insulating layers 167 and 135. Otherwise, it is preferable to form the mask layer 169 with a predetermined thickness sufficient for being used as an etch mask for the upper and the lower mold insulating layers 167 and 135. The patterned mask layer 169 may be in contact with the uppermost layer of the crosstalk prevention barrier.

It is preferable that the uppermost layer, i.e., the second pixel metal interconnection 132a, among the pixel metal interconnections 119a and 132a be in contact with the upper mold insulating layer 167. At this point, the bottom surface of the upper mold insulating layer 167 is configured with a barrier insulating layer 137 for preventing the diffusion of metal atoms in the second pixel metal interconnection 132a.

Peripheral metal interconnections 151b and 166a are arranged in the upper mold insulating layer 167 of the peripheral region b, wherein each of the peripheral metal interconnections 151b and 166a is configured with at least one layer. The pixel metal interconnections 151b and 166a in the upper mold insulating layer 167 includes the same material with the crosstalk prevention barrier.

A transparent insulating layer 175 fills the cavity 173a. Additionally, a color filter may be arranged on the transparent insulating layer 175 and further, a hemispherical optical lens may be formed on the color filter.

According to the image sensor of the present exemplary embodiment having the structure described above, the width of the lower portion of the cavity 173a is defined to the n-type impurity layer 108, and the width of the upper portion of the cavity 173a is greater than the lower portion of the cavity 173a. Accordingly, the quantity of the external light incident on the cavity 173a is increased, to thereby improve the photosensitivity of the image sensor. In addition, crosstalk between adjacent pixels is minimized by the crosstalk prevention barrier so that signal distortion of the pixels may be minimized as well.

As described above, according to the present exemplary of the invention, after forming the dummy pattern in the upper mold insulating layer formed over the photodiode and then exposing the lower mold insulating layer by selectively removing the dummy pattern, the cavity is formed by anisotropically etching the exposed lower mold insulating layer. Accordingly, since the etch amount for the insulating layers is significantly reduced with the anisotropic etch for forming the cavity in comparison with the conventional art, the sidewalls of the cavity may be formed almost vertically. As a result, the cavity, i.e., the open region of the photodiode, can be maximally broadened to enhance the photosensitivity of the image sensor. In addition, the entire surface or the edge of the upper mold insulating layer disposed between the photodiodes is concurrently etched in the anisotropic etch. Thus, the width of the cavity is increased so that the image sensor can receive much more light. Consequently, the intensity of the light incident on the photodiode increases to thereby improve the photosensitivity of the image sensor.

In addition to the above, since the crosstalk prevention barrier is formed in the upper mold insulating layer formed between the photodiodes according to the exemplary embodiments of the present invention, crosstalk between adjacent pixels can be minimized by the crosstalk prevention barrier so that signal distortion of the pixels may be minimized as well.

Having described the exemplary embodiments of the present invention, it is further noted that it is readily apparent to those of reasonable skill in the art that various modifications may be made without departing from the spirit and scope of the invention which is defined by metes and bounds of the appended claims.

What is claimed is:

1. A method of forming an image sensor, the method comprising:
forming a protection insulating layer, a lower mold insulating layer and an upper mold insulating layer over a semiconductor substrate in which a plurality of photodiodes are spaced apart from one another;
forming a dummy pattern contact with the lower mold insulating layer in the upper mold insulating layer;
forming a preliminary cavity exposing the lower mold insulating layer contact with the dummy pattern by selectively removing the dummy pattern; and
forming a cavity exposing the protection insulating layer over the photodiode by anisotropically etching the exposed lower mold insulating layer.

2. The method of claim 1, wherein the forming of the upper mold insulating layer and the dummy pattern comprises:
forming an interconnection mold layer over the lower mold insulating layer;
forming a dummy opening in the interconnection mold layer; and
forming a filling pattern filling the dummy opening,
wherein the upper mold insulating layer comprises the interconnection mold layer and the dummy pattern comprises the filling pattern.

3. The method of claim 2, wherein the forming of the interconnection mold layer, the forming of the dummy opening and the forming of the filling pattern are performed a plurality of times, in which the upper mold insulating layer comprises a plurality of stacked interconnection mold layers and the dummy pattern comprises a plurality of stacked filling patterns, the filling pattern disposed at a lowermost portion of the stacked filling patterns being in contact with the lower mold insulating layer and the filling pattern disposed at an uppermost portion being exposed.

4. The method of claim 2, wherein the interconnection mold layer comprises a barrier insulating layer and an interlayer dielectric layer stacked in sequence, the barrier insulating having an etching selectivity with respect to the interlayer dielectric layer.

5. The method of claim 1, further comprising forming a peripheral metal interconnection with at least one layer in the upper mold insulating layer of a peripheral region, wherein the dummy pattern and the peripheral metal interconnection with at least one layer are formed of the same material, the semiconductor substrate having a pixel region where the photodiodes are formed and the peripheral region where a peripheral circuit is formed.

6. The method of any one of claims 1, wherein a portion of the upper mold insulating layer disposed between the photodiodes is etched by the anisotropic etching.

7. The method of claim 6, further comprising:
forming a mask layer on the upper mold insulating layer; and
forming an opening exposing the dummy pattern by patterning the mask layer,
wherein a width of the patterned mask layer formed on the upper mold insulating layer disposed between the photodiodes is less than a width of the upper mold insulating layer disposed between the photodiodes, the lower mold insulating layer and edges of the upper mold insulating layer disposed between the photodiodes being etched by performing the anisotropic etching using the patterned mask layer as an etch mask.

8. The method of claim 7, further comprising forming a crosstalk prevention barrier in the upper mold insulating layer, wherein the crosstalk barrier is disposed under the patterned mask layer formed between the photodiodes.

9. The method of claim 8, wherein the crosstalk prevention barrier is upwardly spaced apart from a top surface of the lower mold insulating layer.

10. The method of claim 8, wherein the crosstalk prevention barrier and the dummy pattern are formed of the same material.

11. The method of claim 7, further comprising forming a pixel metal interconnection with at least one layer in the lower mold insulating layer, the pixel metal interconnection being formed in the lower mold insulating layer disposed between the photodiodes, wherein a lower portion of the upper mold insulating layer disposed over the pixel metal interconnection remains in anisotropically etching.

12. The method of claim 11, wherein a top surface of the pixel metal interconnection is in contact with the remained upper mold insulating layer and a bottom surface of the upper mold insulating layer is formed of an insulating material for preventing diffusion of metal atoms in the pixel metal interconnection.

13. The method of claim 1, wherein an entire surface of the upper mold insulating layer disposed between the photodiodes are etched by the anisotropic etch.

14. The method of claim 13, further comprising forming a pixel metal interconnection with at least one layer in the lower mold insulating layer, the pixel metal interconnection being formed in the lower mold insulating layer disposed between the photodiodes, wherein the lower portion of the upper mold insulating layer disposed over the pixel metal interconnection remains in the anisotropic etch.

15. The method of claim 14, wherein a top surface of the pixel metal interconnection is in contact with the remained upper mold insulating layer, and a bottom surface of the upper mold insulating layer is formed of an insulating material for preventing diffusion of metal atoms in the pixel metal interconnection.

16. The method of any one of claims 1, wherein the dummy pattern is removed by a wet etch.

17. The method of any one of claims 1, further comprising, after the forming of the cavity, forming a transparent insulating layer filling the cavity over the semiconductor substrate.

18. An image sensor comprising:
a semiconductor substrate in which a plurality of photodiodes are spaced apart from one another;
a protection insulating layer, a lower mold insulating layer and an upper mold insulating layer stacked in sequence over the semiconductor substrate;
a transparent insulating layer filling a cavity, wherein the cavity is formed such that it successively penetrates through the upper and the lower mold insulating layers to expose the protection insulating layer disposed over the photodiode; and
a crosstalk prevention barrier formed in the upper mold insulating layer disposed between the photodiodes.

19. The image sensor of claim 18, wherein at least a portion of the cavity formed in the upper mold insulating layer has a width greater than a width of the cavity formed in the lower mold insulating layer.

20. The image sensor of claim 18, further comprising a peripheral metal interconnection with at least one layer in the upper mold insulating layer of a peripheral region, wherein the crosstalk prevention barrier comprises a material which is the same as a material of the peripheral metal interconnection, the semiconductor substrate having a pixel region where the photodiodes are formed and the peripheral region where a peripheral circuit is formed.

21. The image sensor of any one of claims 18, further comprising a pixel metal interconnection with at least one layer in the lower mold insulating layer disposed between the photodiodes.

22. The image sensor of claim 21, wherein the crosstalk prevention barrier is arranged upwardly spaced apart from the lower mold insulating layer, and a lower portion of the upper mold insulating layer disposed under the crosstalk prevention barrier covers the lower mold insulating layer disposed between the photodiodes.

23. The image sensor of claim 21, wherein the pixel metal interconnection is in contact with the upper mold insulating layer and a bottom surface of the upper mold insulating layer is formed of an insulating material for protecting diffusion of metal atoms in the pixel metal interconnection.
